(19) United States
(12) Patent Application Publication
(10) Pub. No.: US 2008/0096322 A1
(43) Pub. Date: Apr. 24, 2008

(54) Manufacturing method of semiconductor chip

(75) Inventor: Akihiko Nomura, Miyazaki (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO., LTD, Tokyo (JP)

(21) Appl. No.: 11/902,430

(22) Filed: Sep. 21, 2007

(30) Foreign Application Priority Data
Oct. 23, 2006 (JP) 2006-287431

(51) Int. Cl. H01L 21/00

(52) U.S. Cl. 438/114; 257/E21.002

(57) ABSTRACT

The present invention provides a method of manufacturing a semiconductor chip formed with an adhesive film at a back surface thereof, comprising the steps of applying a die bond material onto a dummy wafer by a spin coat method to form a coating film, bonding a back surface of a semiconductor wafer onto the coating film of the die bond material formed over the dummy wafer, performing fractionalization for dividing the semiconductor wafer to form pieces, and peeling off the pieces from above the dummy wafer and transferring the coating film of the die bond material to back surfaces of the pieces to form adhesive films.

### BACKGROUND OF THE INVENTION

The present invention relates to a method of manufacturing a semiconductor chip such as a sensor chip formed with an adhesive film at its back surface.

A conventional semiconductor package is formed in the following manner. Paste comprised of a polyimide resin having thermal plasticity is applied onto a back surface of a semiconductor wafer by a spin coat method and thereafter dried by heating to form a polyimide resin layer. The semiconductor wafer in which a UV tape reduced in adhesive power due to the application of ultraviolet rays is attached onto the polyimide resin layer is divided by dicing to form pieces or fractions. The pieces are taken or peeled off from the UV tape to form semiconductor chips each formed with an adhesive film comprised of the polyimide resin layer at its back surface. The polyimide resin layer of each semiconductor chip is pressed against a die pad used as a bonding plate, and the die pad is heated by a heat stage to bond each semiconductor chip onto the die pad (refer to, for example, a patent document 1 (Japanese Unexamined Patent Publication No. Hei 8(1996)-236554 (Paragraphs 0034-0038 in page 5 and FIGS. 2 and 3)).

In general, spatial apertures or openings are formed at a back surface of a semiconductor wafer in order to form space around a plumb portion of each sensor chip used as a semiconductor chip provided in a semiconductor acceleration sensor.

In the related art referred above, however, the paste comprised of the polyimide resin used as a dicing material is applied onto the back surface of the semiconductor wafer by the spin coat method and thereafter dried by heating to form the adhesive film. Therefore, there is a fear that in the case of the semiconductor wafer having the openings at its back surface as in the semiconductor wafer for forming the sensor chips each used for the semiconductor acceleration sensor, the paste is intruded into the space through the openings, and thereafter, the plumb portions or the like are fixed when the paste is dried by heating,

Therefore, there are problems in that when the dicing material is applied to a die bond portion of a dicing member using an applying nozzle connected to a mechanical or air-pump type dispenser, and the back surface of each sensor chip is placed thereon, non-uniformity is easy to occur in the thickness of a coating film upon application of the dicing material, and the characteristic of the semiconductor acceleration sensor changes due to distortion of the sensor chip caused by the deviation of thermal expansion, thereby degrading its quality.

### SUMMARY OF THE INVENTION

The present invention has been made to solve the above problems. It is an object of the present invention to provide means for forming an adhesive film having a uniform thickness on a back surface of each of semiconductor chips formed by fractionalizing a semiconductor wafer.

According to one aspect of the present invention, for attaining the above object, there is provided a method of manufacturing a semiconductor chip formed with an adhesive film at a back surface thereof, comprising the steps of applying a die bond material onto a dummy wafer by a spin coat method to form a coating film, bonding a back surface of a semiconductor wafer onto the coating film of the die bond material formed over the dummy wafer, performing fractionalization for dividing the semiconductor wafer to form pieces, and peeling off the pieces from above the dummy wafer and transferring the coating film of the die bond material to back surfaces of the pieces to form adhesive films.

Thus, the present invention can obtain an advantageous effect in that a coating film of a die bond material having a uniform thickness, which is formed on a dummy wafer, is transferred when pieces or fractions are peeled off, thereby making it possible to form an adhesive film of a uniform thickness on a back surface of each semiconductor chip.

### BRIEF DESCRIPTION OF THE DRAWINGS

While the specification concludes with claims particularly pointing out and distinctly claiming the subject matter which is regarded as the invention, it is believed that the invention, the objects and features of the invention and further objects, features and advantages thereof will be better understood from the following description taken in connection with the accompanying drawings in which:

FIG. 1 is an explanatory diagram showing an upper surface of a semiconductor acceleration sensor illustrative of an embodiment of the present invention;

FIG. 2 is an explanatory diagram illustrating a section taken along sectional line A-A of FIG. 1; and

FIG. 3 is an explanatory diagram showing a method of manufacturing sensor chips employed in the embodiment.

### DETAILED DESCRIPTION OF THE PREFERRED EMBODIMENTS

A preferred embodiment of a semiconductor chip manufacturing method according to the present invention will hereinafter be described with reference to the accompanying drawings.

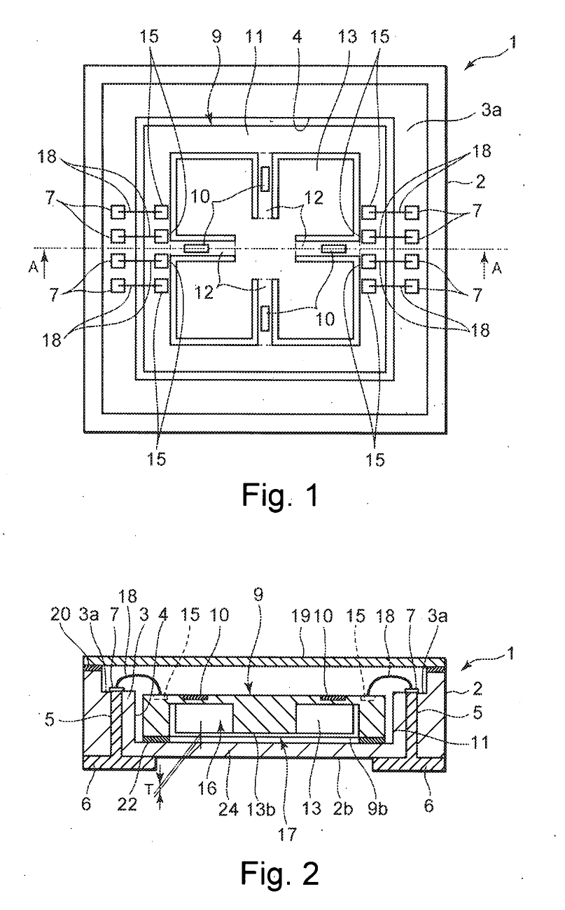

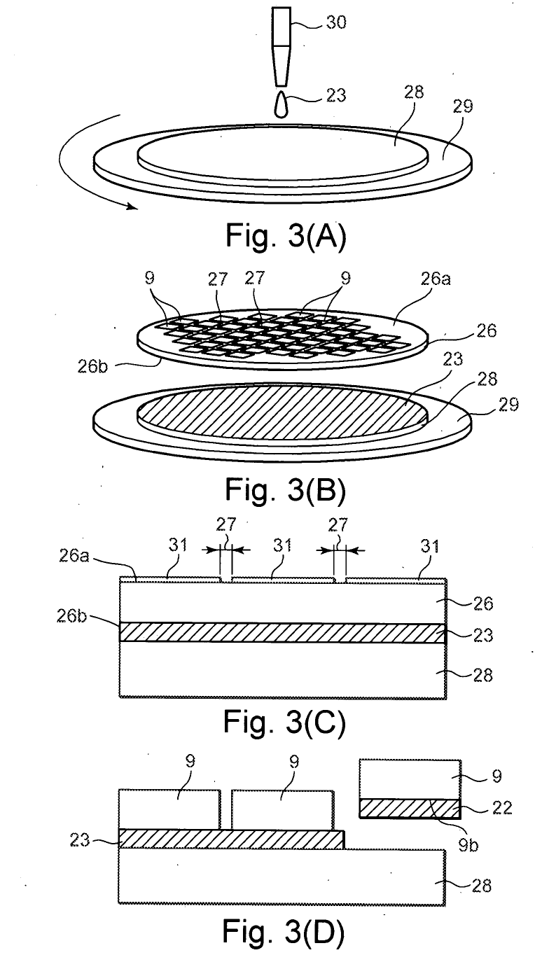

FIG. 1 is an explanatory diagram showing an upper surface of a semiconductor acceleration sensor illustrative of an embodiment, FIG. 2 is an explanatory diagram showing a section taken along sectional line A A of FIG. 1, and FIG. 3 is an explanatory diagram illustrating a method of manufacturing semiconductor chips employed in the embodiment, respectively.

Incidentally, FIG. 1 is shown in a cover-free state.

In FIGS. 1 and 2, reference numeral 1 indicates the semiconductor acceleration sensor used as a semiconductor package.

Reference numeral 2 indicates a case which is a measure-shaped member fabricated by ceramic or the like having a concave portion 4 formed with an intermediate stage portion 3. A plurality of internal terminals 7 electrically connected to external terminals 6 for taking out signals to the outside formed at a back surface 2b of the case 2 through plugs 5 having conductivity, which extend through the intermediate stage portion 3 in the direction of depth of the concave portion 4 from a step or steplike surface 3a of the intermediate stage portion 3, are provided at the step surface 3a.

Reference numeral 9 indicates a sensor chip used as a semiconductor chip. It is a sensor chip which outputs acceleration components of three axes comprising an X axis, a Y axis and a Z axis orthogonal to one another, using piezoelements 10 used as measuring elements. Reference numeral 11 indicates a support portion which is a rectangular frame body comprised of silicon (Si), which is formed at the edge portion of the sensor chip 9. A plumb portion 13 suspended by flexible portions 12 formed of thin silicon, which are disposed crosswise, is swingably accommodated inside the support portion 11.

The piezoelements 10 are respectively formed at the flexible portions 12 supported at the respective centers of the four sides of the support portion 11. Pads 15 each formed of a conductive material such as aluminum (Al) are formed at their corresponding surfaces of the opposite two sides of the support portion 11, which are located on the same sides as the surfaces of the flexible portions 12, formed with the piezoelements 10 (the surface of the support portion 11 on the formed side of each pad 15 is called “the front surface of the sensor chip 9” and its opposite side is called “its back surface”).

The piezoelements 10 formed at the flexible portions 12 are respectively internally connected to the predetermined pads 15 formed in the support portion 11.

Thus, the expansion and contraction of the piezoelements 10 due to deformation produced in the flexible portions 12 by swinging of the plumb portion 13 due to acceleration applied to the sensor chip 9 are outputted from the pads 15 as an electric signal.

A step T is formed between the back surface (called “chip back surface 9b”) of the sensor chip 9 according to the present embodiment and the back surface 13b of the plumb portion 13 as shown in FIG. 2. The chip back surface 9b is formed so as to protrude from the back surface 13b of the plumb portion 13.

Thus, space 16 is formed around the plumb portion 13 of the present embodiment. A rectangular aperture or opening 17 of the space 16 is defined at the chip back surface 9b.

Reference numerals 18 indicate wires, which are metal thin wires formed of a conductive material such as gold (Au). Each of the wires 18 has the function of electrically connecting each of the internal terminals 7 formed on the step surface 3a of the intermediate stage portion 3 of the case 3 and each of the pads 15 of the sensor chip 9.

Reference numeral 19 indicates a cover which is a plate-like member made up of a thin plate such as ceramic, a metal, a resin material or the like. The cover 19 is joined to its corresponding upper surfaces of the side plates of the case 2 by means of a bonding material 20 such as an adhesive, a brazing material or the like.

Thus, the sensor chip 9 is held or accommodated inside a package member comprising the case 2 and the cover 19 to prevent intrusion of dust or the like from outside.

Reference numeral 22 indicates an adhesive or bonding film, which is a film having adhesion, which comprises a die bond material 23 formed on the chip back surface 9b of the sensor chip 9, i.e., the back surface of the support portion 11. The adhesive film 22 has the function of bonding the chip back surface 2b onto its corresponding bottom plate 24 used as a bonging plate, of the case 2.

As the die bond material 23 of the present embodiment, a silicon-oxygen (Si—O) die bond material is used.

In FIG. 3, reference numeral 26 indicates a semiconductor wafer, which is a thin disc comprising silicon. A plurality of sensor chips 9 prior to being divided into pieces or fractions each corresponding to the semiconductor acceleration sensor 1 of the present embodiment are formed in the semiconductor wafer. A plurality of openings 17 for forming spaces 16 around plumb portions 13 are defined in a back surface 26b of the semiconductor wafer 26.

A plurality of scribe areas 27 corresponding to cutting areas used when the semiconductor wafer 26 is divided into pieces or fractions, are set lengthwise and crosswise to a front surface 26a of the semiconductor wafer 26. Therefore, the respective sensor chips 9 are formed in a state of being spaced away from one another.

Reference numeral 28 indicates a dummy wafer which is a disc having a diameter similar to that of the semiconductor wafer 26, which is formed of silicon or glass or the like. The dummy wafer 28 is placed or installed on a turntable 29 of a spin coat device by suction or the like and rotatably driven by the turntable 29.

Reference numeral 30 indicates an applying or coating nozzle, which is coupled or connected to a mechanical or air pump type dispenser provided in the spin coat device and has the function of dripping the die bond material 23 to the center of the rotated disc.

Reference numeral 31 indicates a resist mask, which is a mask pattern formed by subjecting a positive or negative resist applied to the front surface 26 side of the semiconductor wafer 26 by a spin coat method or the like to exposure and development, using photolithography. The resist mask 31 functions as a mask in an etching step or the like of the present embodiment.

A method for manufacturing each semiconductor acceleration sensor according to the present embodiment will be explained below.

A method for manufacturing each sensor chip according to the present embodiment will first be explained in accordance with steps represented by (A) to (D) in FIG. 3.

At FIG. 3 (A), a semiconductor wafer 26 formed with a plurality of sensor chips 9 each used for the semiconductor acceleration sensor 1, and a dummy wafer 28 are prepared. The dummy wafer 28 is placed on its corresponding turntable 29 of the spin coat device. A die bond material 23 is dripped onto the center of the dummy wafer 28 through the applying nozzle 30 while the dummy wafer 28 is being rotated by the turntable 29. The die bond material 23 is applied onto the dummy wafer 28 by the spin coat method to thereby form a coating film of the die bond material 23, which is shown with being hatched in FIG. 3.

The coating film of the die bond material 23 by the spin coat method is formed using a forming condition under which the viscosity of the die bond material 23 is assumed to be 1400 cp (centipoises) and the rotating speed of the dummy wafer 28 is assumed to be 3000 rpm, so that a uniform coating film having a thickness of 5800 nm (nanometers) is obtained.

At FIG. 3 (B), the turntable 29 is stopped after the formation of the coating film of the die bond material 23 to bring the back surface 26b of the semiconductor wafer 26 formed with the plural sensor chips 9 into close contact with the coating film of the die bond material 23 formed on the dummy wafer 28. The semiconductor wafer 26 is pressed to apply or attach the back surface 26b of the semiconductor wafer 26 onto the coating film on the dummy wafer 28, of the die bond material 23.

At FIG. 3 (C), a resist is applied onto the front surface 26a of the semiconductor wafer 26 bonded onto the dummy wafer 28 by the spin coat method to form a resist mask 31 having exposed the scribe areas 27 by photolithography.

At FIG. 3 (D), the semiconductor wafer 26 formed with the dummy wafer 28 and the resist mask 31 bonded onto the same is carried in a dry etching device. Grooves or trenches that penetrate the semiconductor wafer 26 and extend to the coating film of the die bond material 23 are formed by dry etching with the resist mask 31 as a mask, i.e., anisotropic etching for selectively etching silicon. Thus, the semiconductor wafer 26 is divided into peaces or fractions, that is, the sensor chips 9 are formed (fractionalizing step).

Since, at this time, the coating film of the die bond material 23 of the present embodiment is formed by the silicon-oxygen die bond material 23, it functions as an etching stop film at the dry etching.

The resist mask 31 is removed using a remover or release agent and the residual such as the non-exposed resist or the like of the resist mask 31 is removed by cleaning. Thereafter, the fractionalized sensor chips 9 are peeled off from above the dummy wafer 28.

At this time, the coating film of the die bond material 23 is transferred to the chip back surfaces 9b (back surfaces of support portions 11 in the present embodiment) of the sensor chips 9, so that adhesive films 22 each having a uniform thickness are formed on the chip back surfaces 9b.

Each sensor chip 9 according to the present embodiment is manufactured in this way.

When a semiconductor acceleration sensor 1 is formed using the sensor chip 9, the sensor chip 9 is adhered to the center of a bottom face of a concave portion 4 of a case 2 by the uniform adhesive film 22 formed onto the chip back surface 9b and bonded onto its corresponding bottom plate 24 of the case 2. After its bonding, a wire bonder is used to electrically connect between internal terminals 7 formed at a step surface 3a of an intermediate stage portion 3 of the case 2 and pads 15 of the sensor chip 9 by means of wires 18. After the end of the wire bonding step, a cover 19 is bonded onto its corresponding upper surfaces of side plates of the case 2 by a bonding material or member 20. The sensor chip 9 is encapsulated into a package member formed of the cover 9 and the case 2.

The semiconductor acceleration sensor 1 according to the present embodiment shown in FIGS. 1 and 2 is manufactured in this way.

As described above, the adhesive film 22 of the sensor chip 9 of the present embodiment is formed by transferring the coating film of the die bond material 23 formed on the dummy wafer 28 by the spin coat method to the chip back surface 9b of the sensor chip 9. Therefore, the thickness of the coating film of the die bond material 23 formed on the dummy wafer 28 can be made uniform. Further, the thickness of the adhesive film 22 formed on the chip back surface 9b is uniformized so that the sensor chip 9 can be attached to the bottom plate 24 of the case 2. Thus, variations in the measured value of acceleration with non-uniformity of the thickness are prevented, thereby making it possible to greatly enhance the quality of the semiconductor acceleration sensor 1.

Since the adhesive film 22 of the chip back surface 9b is formed by transferring the coating film of the die bond material 23 formed on the dummy wafer 28, the adhesive or the like is not intruded from each opening 17 defined in the back surface 26b of the semiconductor wafer 26 to the space 16 existing around the plumb portion 13 even when the semiconductor wafer 26 having the openings 17 defined in the back surface 26b is used. It is thus possible to prevent fixing of these portions due to the adhesion of the adhesive or the like to the plumb portion 13 and the flexible portions 12.

Further, since the back surface of the support portion 11, corresponding to the chip back surface 9b is formed so as to protrude from the back surface 13b of the plumb portion 13 by the step T, the coating film of the die bond material 23 is not transferred to the back surface 13b of the plumb portion 13.

Furthermore, since the die bond material 23 is used as an adhesive used for the dummy wafer 28 and the pre-fractionalization semiconductor wafer 26, the dummy wafer 28 can be used as a support table for the dry etching device without using another adhesive. Thus, the semiconductor wafer 26 can perfectly be fractionalized within the dry etching device and brought into fractionization without giving a shock to the semiconductor wafer 26, whereby the breakage of the flexible portions 12 or the like of each sensor chip 9 is prevented and the yield of each sensor chip at its manufacture can be enhanced.

Still further, since the adhesive film 22 is formed on the chip back surface 9b when each of the sensor chips 9 is peeled off from the dummy wafer 28, the sensor chip 9 can be bonded onto the bottom plate 24 of the case as it is, and hence a process for manufacturing a semiconductor package can be simplified.

Incidentally, although the thickness of the coating film of the die bond material 23 formed by the spin coat method has been explained as being 5800 nm or so at Step FIG. 3 (A) referred to above, the thickness of the coating film is not limited to it and may be either thinner or thicker than the above.

In this case, the thickness of the coating film may be determined by suitably changing the settings of the viscosity of the die bond material 23 and the rotational speed of the dummy wafer 28.

Assuming that, for example, the viscosity of the die bond material 23 is 10 cp and the rotational speed of the dummy wafer 28 is 3000 rpm, a uniform coating film of about 1000 nm-thick is obtained. Assuming that the viscosity of the die bond material 23 is 1400 cp and the rotational speed of the dummy wafer 28 is 2000 rpm, a uniform coating film of about 8000 nm-thick is obtained.

In the present embodiment as described above, the adhesive film of the sensor chip of each semiconductor acceleration sensor is formed by applying the die bond material onto the dummy wafer by the spin coat method to form the coating film, bonding the back surface of the semiconductor wafer onto the coating film, dividing the semiconductor wafer into the pieces or fractions, peeling off the semiconductor chips corresponding to the divided fractions from above the dummy wafer and transferring the coating film of the die bond material to the back surfaces of the sensor chips. Thus, even when the semiconductor wafer having the openings at its back surface is used, the coating film of the die bond material having the uniform thickness, which is formed on the dummy wafer, is transferred when the fractionalized sensor chips are peeled off, so that the adhesive film having the uniform thickness can be formed on the back surface of each sensor chip. The characteristic of the semiconductor acceleration sensor at the time that each sensor chip is attached to the package member is stabilized to make it possible to greatly enhance the quality of the semiconductor acceleration sensor.

Since dry etching does the step of fractionalizing the semiconductor wafer, the semiconductor wafer can be brought into fractionization without giving any shock thereto. It is also possible to prevent breakage of the flexible portions or the like of each sensor chip and enhance the yield of each sensor chip at its manufacture.

Further, since the die bond material is set as the silicon-oxygen die bond material, the coating film of the die bond material can be used as an etching stop film at the dry etching. Thus, the formation of other etching stop film such as silicon oxide (SiO₂) is made unnecessary, and the process of manufacturing the semiconductor acceleration sensor can be simplified.

Furthermore, the thickness of the coating film of the die bond material formed on the dummy wafer is set based on the viscosity of the die bond material and the rotational speed of the dummy wafer. It is, therefore, possible to easily control the thickness of the coating film of the die bond material.

Although the above embodiment has explained with the semiconductor chip as the sensor chip for the semiconductor acceleration sensor, the semiconductor chip is not limited to the above. The semiconductor chip may be a sensor chip such as a pressure sensor or may be an IC chip or the like. In short, even though any one is taken if the semiconductor chips formed by fractionalizing the semiconductor wafer are bonded onto their corresponding bonding plates or board by an adhesive film, an advantageous effect similar to the above can be obtained if the adhesive film based on the manufacturing method of the present invention is formed.

Although the above embodiment has explained with the package member as the enclosed or encapsulated type in which the measure-shaped case is provided with the cover, the package member may be only the measure-shaped case or an open type package member formed by a flat plate.

Further, although the bonding plate has been explained as being of the bottom plate of the measure-shaped case, the bonding plate may be a flat plate itself of a package member formed by the flat plate or an upper surface or the like of another IC chip or the like.

Furthermore, although the above embodiment has explained the case in which the coating film of the silicon-oxygen die bond material is used as the etching stop film in the step of fractionalizing the semiconductor wafer by dry etching, the use of the coating film of the silicon-oxygen die bond material as the etching stop film makes it possible to use the coating film even in any semiconductor chip manufacturing process if the semiconductor chips formed by fractionalizing the semiconductor wafer by dry etching are taken.

Still further, although the above embodiment has explained with the die bond material as the silicon-oxygen die bond material, a resin or epoxy die bond material may be used.

Still further, although the above embodiment has explained the case in which the division of the semiconductor wafer in its fractionalizing step is done by dry etching, the semiconductor wafer may be divided mechanically using a dicing blade or the like.

While the preferred forms of the present invention have been described, it is to be understood that modifications will be apparent to those skilled in the art without departing from the spirit of the invention. The scope of the invention is to be determined solely by the following claims.

What is claimed is:

1. A method of manufacturing a semiconductor chip formed with an adhesive film at a back surface thereof, comprising the following steps of:
applying a die bond material onto a dummy wafer by a spin coat method to form a coating film;
bonding a back surface of a semiconductor wafer onto the coating film of the die bond material formed over the dummy wafer;
performing fractionalization for dividing the semiconductor wafer to form pieces; and
peeling off the pieces from above the dummy wafer and transferring the coating film of the die bond material to back surfaces of the pieces to form adhesive films.

2. The method according to claim 1, wherein the fractionalizing step is done by dry etching.

3. The method according to claim 2, wherein the die bond material is used as a silicon-oxygen die bond material.

4. The method according to claim 1, wherein the thickness of the coating film of the die bond material, which is formed over the dummy wafer, is set based on viscosity of the die bond material and a rotational speed of the dummy wafer.

5. The method according to claim 1, wherein the semiconductor wafer has openings at the back surface thereof.
